(19) United States
(12) Patent Application Publication
(10) Pub. No.: US 2017/0149255 A1
(43) Pub. Date: May 25, 2017

(54) S-BAS Smart Battery Administration System

(71) Applicant: David Garcia-Acosta, Tempe, AZ (US)

(72) Inventor: David Garcia-Acosta, Tempe, AZ (US)

(21) Appl. No.: 14/950,768

(22) Filed: Nov. 24, 2015

(51) Int. Cl. H02J 7/00; G01R 31/36

(52) U.S. Cl. CPC H02J 7/0021; H02J 7/0052; G01R 31/3624

(57) ABSTRACT

A battery charging system that provides for battery charging optimization, providing a new and improved maximization of efficiencies in battery charging. A battery charging system that controls battery charge time duration and cooling time duration through automation of the battery charging process, acquiring necessary data of the battery charging process in real time, and establishes automatic maintenance notifications. A battery charging system that optimizes battery charger utilization, and optimizes battery charging and discharging duration timing, and avoids premature battery damage.

### CROSS-REFERENCE TO RELATED APPLICATIONS

“Not Applicable”

### STATEMENT REGARDING FEDERALLY SPONSORED RESEARCH OR DEVELOPMENT

“Not Applicable”

### THE NAMES OF THE PARTIES TO A JOINT RESEARCH AGREEMENT

“Not Applicable”

### INCORPORATION-BY-REFERENCE OF MATERIAL SUBMITTED ON A COMPACT DISC OR AS A TEXT FILE VIA THE OFFICE ELECTRONIC FILING SYSTEM (EFS-WEB)

Fig1MicrocontrollerProg.txt

Fig2MicrocontrollerProg.txt

Fig3MicrocontrollerProg.txt

Fig4MicrocontrollerProg.txt

### STATEMENT REGARDING PRIOR DISCLOSURES BY THE INVENTOR OR JOINT INVENTORS

“Not Applicable”

### BACKGROUND OF THE INVENTION

(1) Field of the Invention

The present invention relates, in general, to battery charging systems, and more particularly to a novel system for charging industrial batteries.

More particularly, this invention relates to an automated smart battery administration system to control charging of industrial batteries.

(2) Description of Related Art Including Information Disclosed Under 37 CFR 1.97 and 1.98

Modern industry is currently provided with bigger and more complex material handling systems which includes the vast use of electric forklifts and their derivate equipment such as pallet jacks, pallet elevators, etc.

All of these industrial vehicles and equipment are being powered by industrial batteries with standardized voltages of 24 VDC, 36 VDC and 48 VDC in the U.S.A. Europe uses different voltages which are not mentioned in this disclosure, but are not excluded from the scope of the proposed system. Such industrial batteries have been also designed and commercially standardized to provide enough power to operate a forklift for 8 hours. Then, these batteries are designed to be re-charged in a standard period of 8 hours and require a cooling time period of 8 hours as well, for a total cycle of 24 hours (charging, cooling and powering modes=8+8+8=24 Hours).

Battery chargers are currently available on different voltages, charging type, automation level, duty cycle, enclosure type, etc. However, the ultimate goal is to charge the battery safely and efficiently.

Forklift, battery and battery charger manufacturers have been working together to provide integrated solutions to end users which consolidate battery charging and cooling in areas such as battery rooms. A battery room is a dedicated area in the end user premises in which the battery chargers are permanently installed and connected to the AC power system of the facility, and the batteries are being charged, handled and serviced, and finally where the forklifts (or other electric mobile material handling equipment) exchange their batteries in an efficient and safe way.

As in the majority of the industry, there are available options of mechanization and automation, depending on the end user purpose and requirements. Specifically, there are two types of battery rooms:
a) Gantry or overhead crane: the batteries are being handled by a gantry or overhead crane, via hooks; the battery is suspended from the crane's hook by a special spreader bar. The battery room operator (person) controls the crane and walks behind the suspended load.
b) Extractor: the batteries are being handled by dedicated equipment mounted on rails/floor and the battery is being grabbed by the extractor machine via hydraulic powered arms. The operator controls the extractor from the driver seat and travels with the extractor all the time during the battery handling process.

Battery handling process: This process is the most commonly used by battery rooms with multiple battery chargers and batteries, including the manufacturing industry, food process plants, distribution centers, etc. The battery handling process includes the following steps:
1. The forklift driver (driver) arrives to the battery room and contact the person in charge of the battery room (operator). The operator records (manually or electronically) the data of such event such as forklift ID, driver ID, battery ID and voltage.
2. The operator directs the driver to the forklift staging area. The driver gets off the vehicle. The operator then proceeds to remove the battery from the forklift truck. If the operator uses a crane—gantry or overhead—then he will hook up the battery and remove it from the forklift truck and locate the battery inside of an empty space of the battery rack.
3. Then, the operator hooks up a charged battery from the battery rack and rigs it back to the forklift truck. The driver now is ready and leaves the battery room.
4. The operator connects the empty (spent) battery to the battery charger. The battery charger is normally located on top of the battery rack and is provided with a long cord and a standard battery charger plug, known in the industry as an Anderson plug. All batteries are provided also with an Anderson connector. The operator might encounter one of the following scenarios and problems:
   4.1 The battery charger is currently busy charging another battery on the same battery rack, normally in the same column. In this case the operator must leave the spent battery unplugged and wait for the other battery to finish its 8 hour cycle of charging. The operator must be aware and keep track of this event. In order to avoid leaving a full battery connected to a battery charger, as in point 4.2, which even when the battery charger automatically stops charging, time is of the essence and the operator must use an 8 hour span to charge the battery while the previously charged battery is on a cooling mode.
   4.2 The battery charger is currently connected to a battery that is full and is now in its cooling off cycle of 8 hours. In this scenario, the operator should be aware and 100% sure (by visual indicators of the battery charger) of the “full charge” condition and proceed to disconnect the charged battery and connect the spent (waiting to be charged) battery. Some cases require the operator to initiate the battery charger by pressing a reset button located in the battery charger. On both scenarios one may find a third scenario 4.3.
   4.3 The operator extracts the spent battery from the forklift truck and finds out that the battery charger is charging one battery (as in point 4.1) but the second battery on the rack has not completed its cooling cycle. The operator has no choice but to load the forklift with a “hot” battery. This decision will lead to run a “hot” battery which will not be optimal and will lose its charge faster.
   4.4 If the operator uses a battery extractor as described above, this may be more efficient while handling the batteries because it can extract the fully charged battery from the battery rack, place it in the battery extractor and transport it to the forklift stage. Then, it can extract the battery from the forklift truck and install the fully charged battery in it. Even though, the operator may find himself in the situations 4.1 or 4.2 or 4.3, which affects the bottom line.
   4.5 The currently adopted arrangements of battery racks are provided with a single cord and plug per each battery charger, such cord must be long enough to reach the farthest battery in the rack. Frequently, the operator forgets to coil up or put away the cord and leaves the cord on the floor, potentially and evidently; forklifts and/or the battery extractor itself runs over the cord and plug, causing damage.
   4.6 Besides the situations where the batteries are not being properly charged or cooled, the operator is responsible to inspect and maintain the batteries. One task is to wash each battery after a certain period of use, for instance every three charges. In this case the operator must extract the battery from the battery rack and transport it to a wash station located within the battery room. After washing, the battery must be placed back to the rack,
   4.7 Similarly, batteries require maintaining their levels of electrolyte; an operator must keep track of the inspections and refill the levels of electrolyte.
   4.8 Expanding on problems to solve or areas of opportunity in industrial battery charging:
      The vast majority of the industry requires reliable and useful data to administer the battery charging system.
      Currently, bar code reading systems, assisted by data bases and computers are used; these systems are basically data entry.
      However, such systems basically register the events, and data in order to provide a report displaying charging, cooling and service history of each battery and are not real time systems.
      Such systems neglect to monitor in real time the condition of each battery; therefore these systems do not provide a useful tool for planning or operating the entire battery room system.

Moreover, the industry has been refining technology and methods in battery charging which also has defined the most common Battery charger to battery Ratio:

Battery charger to battery Ratio: The standard and more economically feasible arrangement is to have one battery charger per forklift and two batteries per battery charger as minimum case, where the end user operates a forklift for two 8-hour shifts. However, if the end user requires operating three 8-hour shifts, then, the minimum number of batteries per battery charger are three batteries.

However, some end users prefer to provide one (1) battery charger per each one-and-a-half (1.5) batteries. This arrangement requires that the battery charger only has one assigned battery space and the battery charger connector is permanently attached to such space. The battery is connected (plugged) to such wiring and remains connected until the battery room operator decides to disconnect it, normally until that specific battery is going to be used, therefore, the battery is always connected to its charger, even when the charger has completed the charging cycle and remains idle, restraining using the charger for another battery.

We have identified battery charging methods and operations to date, and identified its problems.

Accordingly, it would be advantageous to introduce a battery charging system that guarantees total battery optimization.

It is an object of the present invention to provide a new and improved maximization of efficiencies in battery charging.

It is another object of the present invention to provide a battery charging system that controls battery charge time duration and cooling time duration.

It is a further object of the present invention to maximize automation of the battery charging process.

It is still a further object of the present invention to provide a battery charging system that acquires necessary data of the battery charging process in real time.

It is still a further object of the present invention to provide a battery charging system that establishes automatic maintenance notifications.

It is still a further object of the present invention to provide a battery charging system that establishes automatic maintenance control.

It is still a further object of the present invention to provide a battery charging system that optimizes battery charger utilization.

It is still a further object of the present invention to provide a battery charging system that minimizes human error in the logistics of the battery charging process.

It is still a further object of the present invention to provide a battery charging system that avoids arbitrary battery charging and discharging durations and timing.

It is still a further object of the present invention to provide a battery charging system that reduces premature battery damage.

It is still yet a further object of the present invention to provide a battery charging system that optimizes equipment availability.

### BRIEF SUMMARY OF THE INVENTION

After thoroughly analyzing the situations and problems that a standard industrial battery room presents, the present invention introduces a feasible, reliable and innovative system called Smart Battery Administration System (S-BAS).

The Smart Battery Administration System (S-BAS) is a battery charging system that provides for battery charging optimization, providing a new and improved maximization of efficiencies in battery charging; a battery charging system that controls battery charge time duration and cooling time duration through automation of the battery charging process, acquiring necessary data of the battery charging process in real time, and establishes automatic maintenance notifications. S-BAS is a battery charging system that optimizes battery charger utilization, and optimizes battery charging and discharging duration timing, and avoids premature battery damage.

S-BAS is a practical development system, which will be useful at battery charging stations where administrative controls are not enough to guarantee total battery optimization, maximization of efficiencies and equipment duration with strict control of battery charge and cooling times. The S-BAS system has been designed with a practical approach to a standard battery charging room, maximizing automation of the battery charge process, acquiring necessary data, establishing automatic maintenance notifications and control, saving power by optimizing battery charger usage and minimizing human error in the logistics of the battery room area and avoiding arbitrary charging and discharge timing that produces premature battery damage and equipment unavailability.

In the logistics of a present battery charging system there are unaccounted factors that prevent an optimal administration of the charge cycles, such as work overload, unaccounted heavy equipment usage, other systems inadequacy, and human error; factors for which the S-BAS system compensates.

The S-BAS system comprises a modular intelligent harness that distributes power from a battery charger or series of battery chargers at a station or rack, to one or several connected batteries. This harness is in constant communication with a monitor and control center that monitors electrical parameters, charge timing and equipment usage. All batteries are also equipped with battery sensor modules that will capture and send identification and electrical data, all in real time. The S-BAS system automates the tasks for achieving maximum battery life and provides significant savings in equipment replacement costs, operation downtime, and underutilized equipment and/or human operator resources.

### BRIEF DESCRIPTION OF THE SEVERAL VIEWS OF THE DRAWING(S)

The foregoing and further and more specific objects and advantages of the instant invention will become readily apparent to those skilled in the art from the following detailed description of a preferred embodiment thereof taken in conjunction with the drawings, in which:

FIG. 1 is a schematic simplified drawing which illustrates a battery charger remote control circuit of the present invention;

FIG. 2 is a schematic simplified drawing which illustrates a neuron circuit of the present invention;

FIG. 3 is a schematic simplified drawing which illustrates a battery sensor circuit of the present invention;

FIG. 4 is a simplified block diagram which illustrates a central monitor and control station of the present invention;

FIG. 5 is a simplified algorithm flow diagram of the present invention, the Smart Battery Administration System, which illustrates the algorithm of Automatic Device Sweep;

FIG. 6 is a simplified algorithm flow diagram of the present invention, the Smart Battery Administration System, which illustrates the algorithm of Charge Request;

FIG. 7 is a simplified algorithm flow diagram of the present invention, the Smart Battery Administration System, which illustrates the algorithm of Battery Request;

FIG. 8 is a simplified block diagram of a traditional battery rack which illustrates traditional battery charger connection;

FIG. 9 is a simplified block diagram of a battery rack configured with the Smart Battery Administration System battery charger connection.

### DETAILED DESCRIPTION OF THE INVENTION

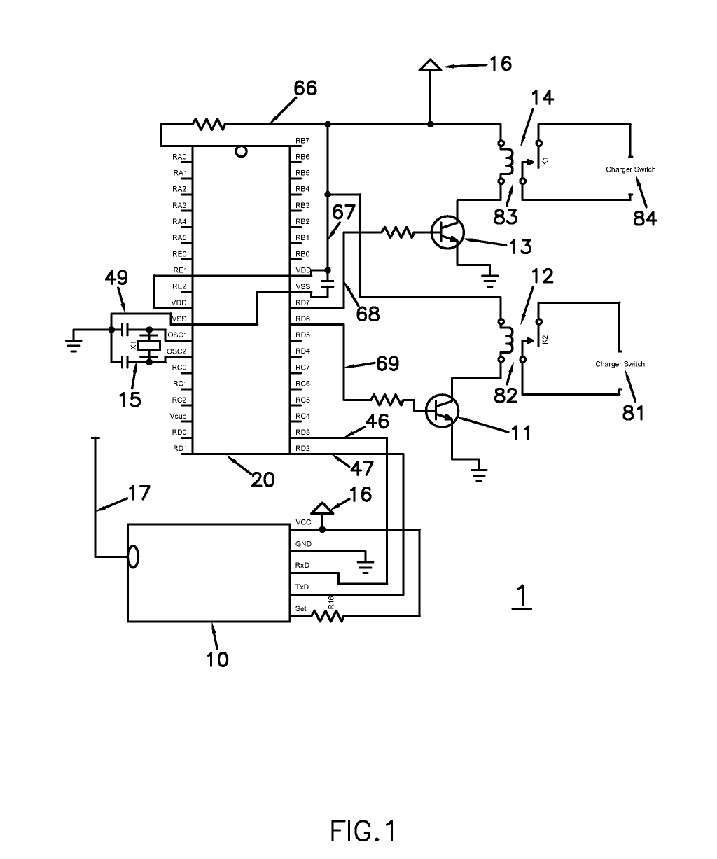

Turning now to the drawings in which like reference characters indicate corresponding elements throughout the several views, attention is first directed to FIG. 1 which illustrates a simplified schematic diagram of a Charger Remote Control 1 of the present invention. This circuit realizes the functions of an operator pressing the charger stop, and equalize (and start, if fitted with a third relay). Incorporated by reference is a programmable microcontroller 20 program incorporated with this patent application named “Fig1MicrocontrollerProg.txt”, a program that controls all actions in the circuitry of FIG. 1.

A programmable microcontroller 20 receives a signal through monitor lead 46 from an RF Radio Modem 10, which is a Radio transceiver, FM radio, USART (Universal serial asynchronous radio transmission). RF Radio Modem 10 is a module that utilizes Frequency modulation at a 433 MHz carrier to transmit digital data on a semi-duplex mode, 1 W of power. Monitor lead 46 is a serial data transmission line (9600 baud, 8 bit, parity none, no stops).

Programmable microcontroller 20 is a Microcontroller chip (or MCU), Microchip (brand) 18F4550, 32K program Flash memory, 10 bit ATD converters. 40 pin DIP (Dual in line package) used in one embodiment of the present invention.

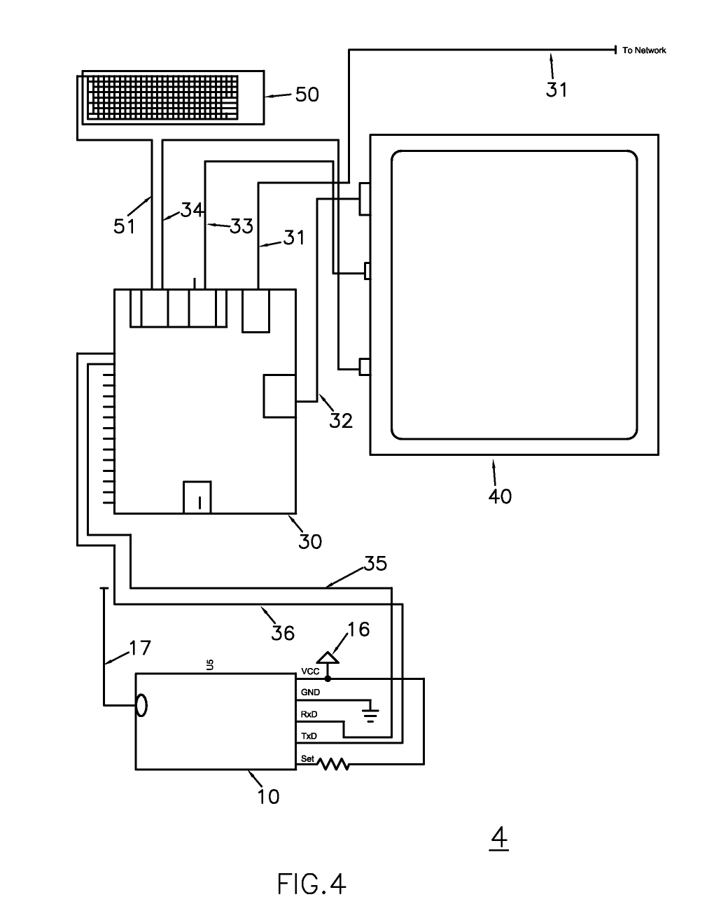

An antenna 17 receives a radio frequency signal from a Monitor and Control Station 4 of the present invention, further described in FIG. 4. Antenna 17 is a radio antenna with a Micro connector and externally mounted unipolar antenna. Tuned (by length) for UHF 433 MHz.

The programmable microcontroller 20 reacts to its internal program and responds to the Monitor and Control Station 4 via transmit lead 47 to activate a transmit signal from RF Radio Modem 10, emanating a radio frequency signal through antenna 17. The programmable microcontroller 20 reacts to the incoming signal via its internal program to send an electrical voltage and current signal via transistor lead 69 to switching transistor 11 to activate transistor 11 to conduct and thereby connect to system ground. Transistor 11 is an NPN transistor used as a power switch and is a 1K ohm base current limiting resistor with a base of 5 volts equals transistor 11 switching GND to an open collector. Transmit lead 47 is a serial data receiving line (9600 baud, 8 bit, parity none, no stops).

By connecting to system ground, transistor 11 allows current to flow from direct current power source 16 to system ground, connecting a circuit from power source 16 to system ground, with this circuit current flowing through coil 12, activating contact switch 82 to close its circuit to charger switch 81, thereby activating and connecting a battery charger to charge a battery. Coil 12 is a 5 volt coil and is a normally open switch in parallel with a charger circuit switch. Power source 16 is a 5 volt direct current source to power various components.

Programmable microcontroller 20 further reacts to an incoming signal via its internal program to send an electrical voltage and current signal via transistor lead 68 to switching transistor 13 to activate transistor 13 to conduct and thereby connect to system ground. Transistor 13 is an NPN transistor used as a power switch, and is a 1K ohm base current limiting resistor, with a base of 5 volts equals transistor switching GND to open collector.

By connecting to system ground, transistor 13 allows current to flow from direct current power source 16 to system ground, connecting a circuit from power source 16 to system ground, with this circuit current flowing through coil 14, activating contact switch 83 to close its circuit to charger switch 84, thereby activating and connecting a battery charger to charge a battery. Coil 14 is a 5 volt coil, a normally open switch in parallel with a charger circuit switch.

Power lead 66 and power lead 67 provide power to programmable microcontroller 20 from power source 16. Power lead 66 is a 5 volt line to keep Microcontroller 20 on auto reset on power up (Memory clear line) thru a current limiting 10K ohm resistor. Power lead 67 is a 5 volt or Power+ line to power microcontroller 20.

Power lead 49 further provides a zero volt, or ground, to an oscillating circuit 15 which connects to programmable microcontroller 20 for internal clock control. Oscillator 15 is a 20 MHz oscillator array with 20 pF reference capacitors to GND. This is the Microcontroller's 20 microprocessor's clock. It pulses at 20 million times per second with zero drift. Power lead 49 is a ground or 0V line for the oscillator circuit.

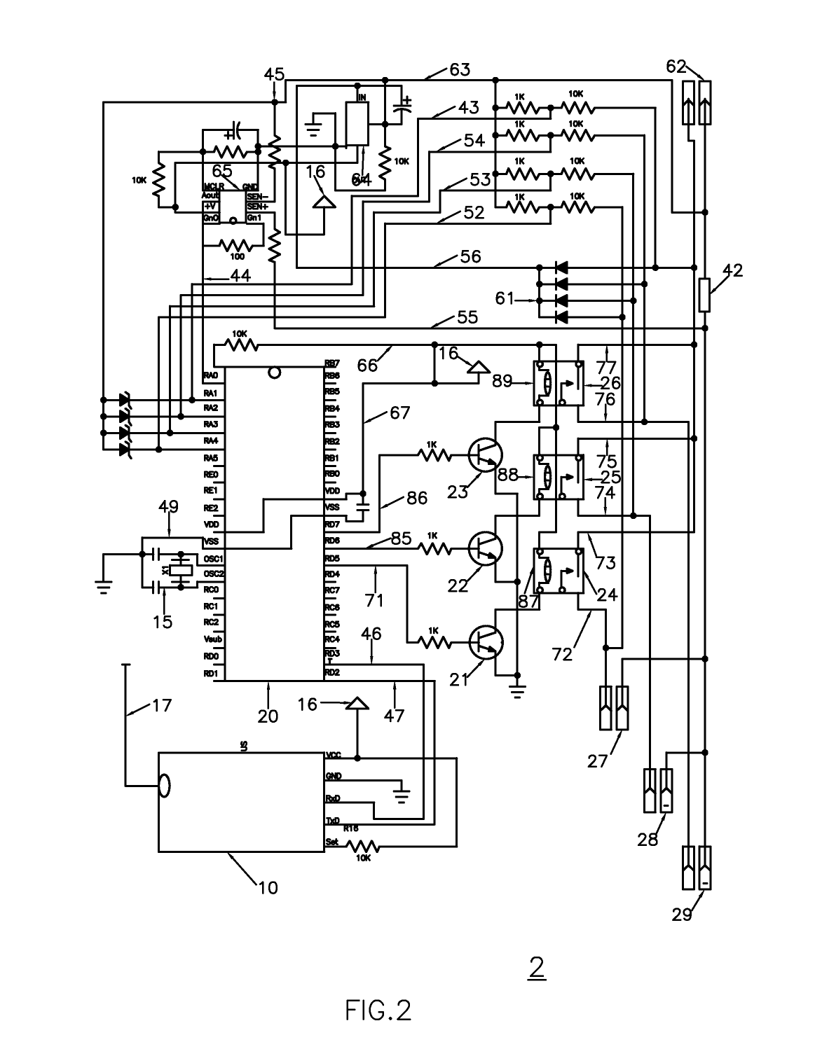

Turning now to FIG. 2 which illustrates a simplified schematic diagram of a Neuron 2 of the present invention. Incorporated by reference is a programmable microcontroller 20 program incorporated with this patent application named “Fig2MicrocontrollerProg.txt”, a program that controls all actions in the circuitry of FIG. 2.

Neuron 2 acts as a current hub to the batteries and at the same time takes all measurements of voltage and current. Antenna 17 of an RF Radio Modem 10 receives a radio frequency signal from a Monitor and Control Station 4 of the present invention, further described in FIG. 4. A programmable microcontroller 20 further receives this radio frequency signal, now converted to an electronic signal through monitor lead 46 from the RF Radio Modem 10. The programmable microcontroller 20 reacts to the incoming electronic signal with its internal program and responds to the Monitor and Control Station 4 via transmit lead 47 to activate a transmit signal from RF Radio Modem 10, emanating a radio frequency signal through antenna 17. The programmable microcontroller 20 also reacts to the incoming signal via its internal program to send an electrical voltage and current signal via transistor lead 71 to switching transistor 21 to activate transistor 21 to conduct and thereby connect its ground lead to system ground. By connecting to system ground, transistor 21 allows current to flow from direct current power source 16 to system ground, connecting a circuit from power source 16 to system ground, with this circuit current flowing through coil 87, activating contact switch 24 to close its circuit to activate lead 72, thereby activating connector pair 27.

The combination of coil 87 and contact switch 24 are known in the industry as solid state switching relays, the same with coil 88 and contact switch 25, and also coil 89 and contact switch 26. Radio modem 10 is a radio transceiver, FM radio, USART (Universal serial asynchronous radio transmission) which utilizes frequency modulation at a 433 MHz carrier to transmit digital data on a semi-duplex mode, utilizing one watt of power.

Contact switch 24 is a Solid State Relay output (Switch +V from a battery charger to Battery #1) 300 A. Contact switch 25 is a Solid State Relay output (Switch +V from a battery charger to Battery #2) 300 A. Contact switch 26 is a Solid State Relay output (Switch +V from a battery charger to Battery #3) 300 A.

Coil 87, coil 88, and coil 89 are Solid State Relays, Optically isolated, activated by 5 volts.

Programmable microcontroller 20 further reacts to an incoming signal via its internal program to send an electrical voltage and current signal via transistor lead 85 to switching transistor 22 to activate transistor 22 to conduct and thereby connect to system ground. By connecting to system ground, transistor 22 allows current to flow from direct current power source 16 to system ground, connecting a circuit from power source 16 to system ground, with this circuit current flowing through coil 88, activating contact switch 25 to close its circuit to activate lead 74, thereby activating connector pair 28. Connector pair 27 is a Universal Battery connector (Anderson 150A) for Battery #1. Connector pair 28 is a Universal Battery connector (Anderson 150A) for Battery #2. Connector pair 29 is a Universal Battery connector (Anderson 150A) for Battery #3. Connector pair 62 is an input Universal Battery connector (Anderson 150A).

Programmable microcontroller 20 further reacts to an incoming signal via its internal program to send an electrical voltage and current signal via transistor lead 86 to switching transistor 23 to activate transistor 23 to conduct and thereby connect its ground lead to system ground. By connecting to system ground, transistor 23 allows current to flow from direct current power source 16 to system ground, connecting a circuit from power source 16 to system ground, with this circuit current flowing through coil 89, activating contact switch 26 to close its circuit to activate lead 76, thereby activating connector pair 29.

Transistors 21, 22, and 23 are NPN transistors used as a power switch, a 1K ohm base current limiting resistors, 5 volts equals transistor switching GND to open collector.

Lead 43 is a voltage line proportional to 7% of charger +V, limited by a 5.1 volt Zener diode. Lead 44 is a 0 to 5 volt line out from an instrumentation Amplifier, proportional to 0 to 200 A of current on shunt. Lead 45 is a negative battery lead to an instrumentation amplifier. Lead 45 is the reference from the current shunt base to measure a small voltage drop on shunt resistor 42, proportional to the current passing thru the shunt.

Lead 52 is a voltage lead 3, proportional to 7% of Battery #3+V, limited by a 5.1 Volt Zener diode. Lead 53 is a voltage line 2, proportional to 7% of Battery #3+V, limited by a 5.1 Volt Zener diode. Lead 54 is a voltage line 1, proportional to 7% of Battery #3+V, limited by a 5.1 Volt Zener diode. Lead 55 is a Battery Negative line to an Instrumentation Amplifier (After shunt, or shunt +). Lead 55 is the reference from the current shunt output to measure a small voltage drop on shunt resistor 42, proportional to the current passing thru the shunt. Lead 56 is a Power+ lead. Voltage from a battery charger and all batteries is isolated by diodes acting as valves. The higher voltage will make the other diodes to polarize. The resulting voltage drives a DC to DC converter circuit (Buck or Mechanical Chopper circuit) that has a 5V regulated output.

Lead 56 is a power lead with voltage from a battery charger and all batteries isolated by diodes 61 acting as valves. The higher voltage will make the other diodes to polarize. The resulting voltage drives a DC to DC converter circuit 64 (Buck or Mechanical Chopper circuit) that has a 5V regulated output.

DC to DC converter 64 is an 18 VDC to 78 VDC input 5 VDC output 600 mA standard.

In the present embodiment Amplifier 65 is an IA620 Instrumentation amplifier to convert shunt voltage to 0 to 5 VDC for Microcontroller's 20 analog to digital converter.

We now identify some of the leads shown on FIG. 2. Lead 66 is a 5V line to keep Microcontroller 20 auto reset on power up (Memory clear line) thru a current limiting 10K ohm resistor. Lead 67 is a 5V or Power+ line to power Programmable Microcontroller 20 and relay coils. Lead 72 is an Output +V line to Battery #1. Lead 73 is an Input +V bus from a battery charger. Lead 74 is an Output +V line to Battery #2. Lead 75 is an Input +V bus from a battery charger. Lead 76 is an Output +V line to Battery #3. Lead 77 is an Input +V bus from a battery charger.

Power lead 66 and power lead 67 provide power to microcontroller 20 from power source 16. Power lead 49 provides power to an oscillating circuit 15 which connects to programmable microcontroller 20 for internal clock control. Oscillating circuit 15 is a 20 MHz oscillator array with 20 pF reference capacitors to GND. This is Microcontroller's 20 clock. It pulses at 20 million times per second with zero drift.

Further, a Neuron 2 of FIG. 2 works as a control node with capacity for up to 3 batteries to be connected to each battery charger, monitoring voltage, current and providing control over the charging current. This control node, Neuron 2, will be self-powered from the battery charger through power source 16 and from the batteries themselves back feeding to power source 16; the required current is minimal and the voltage is universal, being capable of powering itself for weeks, even from spent batteries. If the system has quick battery chargers, a plurality of Neurons 2 can be also interconnected, providing different current paths, to charge batteries that were mistakenly positioned or when the system goes through a high demand time. The Neurons 2 collect and transmit power data from the batteries and if charging is needed, the Neurons 2 receive a battery charger connection signal from the Monitor and Control Station 4 Console, further described in FIG. 4.

Further identifying other components, there is Shunt 42, which is a Current Shunt 200 A 50 mV. Lead 43 is a Voltage line 0, Proportional to 7% of a battery charger +V, limited by a 5.1 V Zener diode. Lead 44 is a 0 to 5 Volt line out from Instrumentation Amplifier 65, proportional to 0 to 200 A of current on Shunt 42. Lead 45 is a Battery Negative line to Instrumentation Amplifier 65. This Lead 45 is the reference from the current Shunt 42 base to measure a small voltage drop on Shunt 42, proportional to the current passing thru Shunt 42. Lead 55 is a Battery Negative line to Instrumentation Amplifier 65.

Lead 55 is the reference from the current Shunt 42 output to measure a small voltage drop on Shunt 42, proportional to the current passing thru Shunt 42. Lead 56 is a Power+ Voltage from a battery charger and a battery which are isolated by a diode acting as valve (Only one line, in the case of the battery sensor). The higher voltage will make the other diodes to polarize. The resulting voltage drives a DC to DC converter 64 which is a circuit (Buck or Mechanical Chopper circuit) that has a 5V regulated output.

Lead 63 is a Power negative (−) Voltage from a battery charger and all batteries, isolated by diodes acting as valves. The higher voltage will make the other diodes to polarize. The resulting voltage drives a DC to DC converter circuit 64 (Buck or Mechanical Chopper circuit) that has a 5V regulated output.

DC to DC converter 64 has 18 to 78 VDC input 5 VDC output 600 mA standard.

Instrumentation Amplifier 65, in the present embodiment is an IA620 Instrumentation amplifier to convert Shunt 42 voltage to 0 to 5 VDC for MCU analog to digital converter.

Lead 66 is a 5V line to keep Microcontroller 20 auto reset on power up (Memory clear line) thru a current limiting 10K ohm resistor.

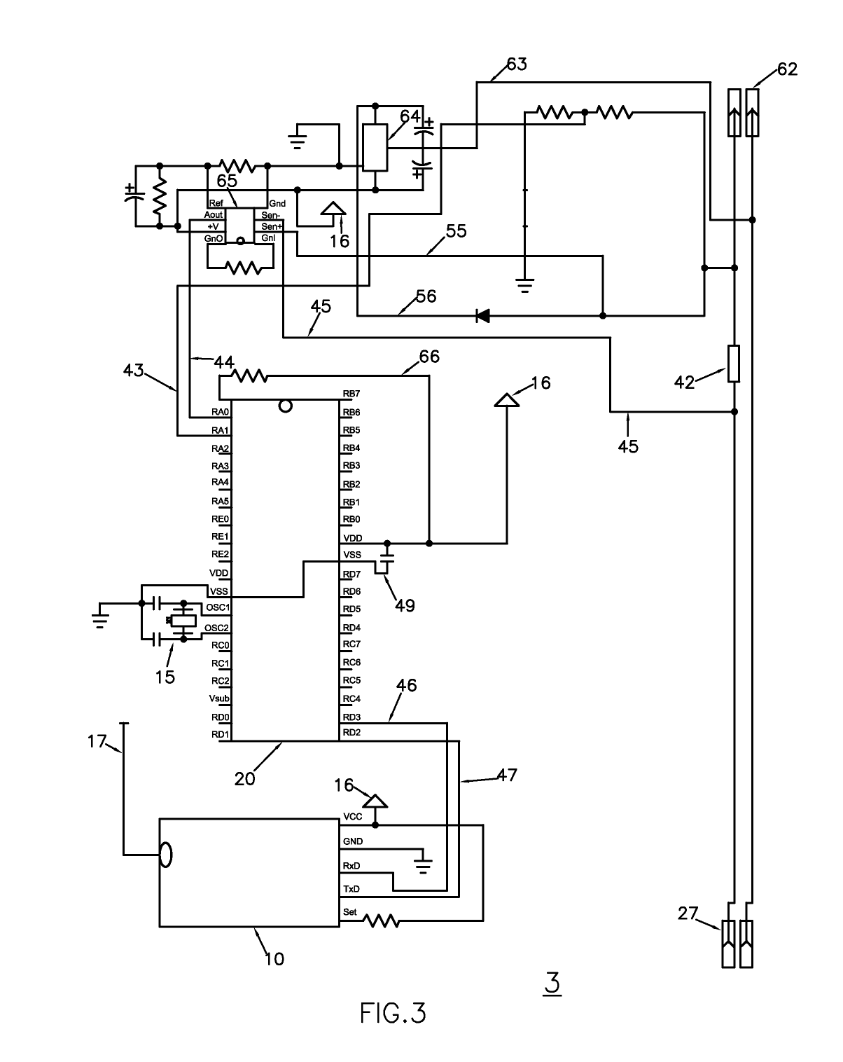

Turning now to FIG. 3 which illustrates a simplified schematic diagram of a Battery Sensor 3 of the present invention. Each battery in the system is fitted with a permanent Battery Sensor 3 which is a current and voltage sensor that transmits data on cue from a Monitor and Control Station 4. Incorporated by reference is a programmable microcontroller 20 program incorporated with this patent application named “Fig3MicrocontrollerProg.txt”, a program that controls all actions in the circuitry of FIG. 3.

Antenna 17 of an RF Radio Modem 10 receives a radio frequency signal from a Monitor and Control Station 4 of the present invention, further described in FIG. 4. A programmable microcontroller 20 further receives this radio frequency signal, now converted to an electronic signal, through monitor lead 46 from the RF Radio Modem 10. The programmable microcontroller 20 reacts to this incoming electronic signal with its internal program and responds to the Monitor and Control Station 4 via transmit lead 47 to activate a transmit signal from RF Radio Modem 10, emanating a radio frequency signal through antenna 17. Microcontroller 20 in the present embodiment is a Microchip (brand) 18F4550 with 32K program Flash memory, 10 bit ATD converters, and 40 pin DIP (Dual in line package).

Further identifying other components, there is Shunt 42, which is a Current Shunt 200 A 50 mV. Lead 43 is a Voltage line 0, Proportional to 7% of a battery charger +V, limited by a 5.1 V Zener diode. Lead 44 is a 0 to 5 Volt line out from Instrumentation Amplifier 65, proportional to 0 to 200 A of current on Shunt 42. Lead 45 is a Battery Negative line to Instrumentation Amplifier 65. This Lead 45 is the reference from the current Shunt 42 base to measure a small voltage drop on Shunt 42, proportional to the current passing thru Shunt 42. Lead 55 is a Battery Negative line to Instrumentation Amplifier 65. Lead 55 is the reference from the current Shunt 42 output to measure a small voltage drop on Shunt 42, proportional to the current passing thru Shunt 42. Lead 56 is a Power+ Voltage from a battery charger and a battery which are isolated by a diode acting as valve (Only one line, in the case of the battery sensor). The higher voltage will make the other diodes to polarize. The resulting voltage drives a DC to DC converter 64 which is a circuit (Buck or Mechanical Chopper circuit) that has a 5V regulated output.

Lead 63 is a Power negative (−) Voltage from a battery charger and all batteries, isolated by diodes acting as valves. The higher voltage will make the other diodes to polarize. The resulting voltage drives a DC to DC converter circuit 64 (Buck or Mechanical Chopper circuit) that has a 5V regulated output.

DC to DC converter 64 has 18 to 78 VDC input 5 VDC output 600 mA standard.

Instrumentation Amplifier 65, in the present embodiment is an IA620 Instrumentation amplifier to convert Shunt 42 voltage to 0 to 5 VDC for MCU analog to digital converter.

Lead 66 is a 5V line to keep Microcontroller 20 auto reset on power up (Memory clear line) thru a current limiting 10K ohm resistor.

Battery Sensor 3 basically monitors the charge condition of a battery and relays this battery charge condition to the Monitor and Control Station 4 for evaluation.

Turning now to FIG. 4 which illustrates a block diagram of a Monitor and Control Station 4 of the present invention. Incorporated by reference is a Single Board Computer 30 program incorporated with this patent application named “Fig4ComputerProg.txt”, a program that controls all actions of the components of FIG. 4.

A Single Board Computer 30 is programmed to monitor the status of the various components of the Smart Battery Administration System S-BAS of the present invention. The Monitor and Control Station 4 of the present invention further comprises a USB Keyboard 50, a Touch Screen 40 and an RF Radio Modem 10.

Antenna 17 of the RF Radio Modem 10 receives component status signals via radio frequency transmissions from components such as a Charger Remote Control 1, Battery Sensors 3, and Neurons 2 of the present invention. A signal from these various system components is delivered to the Single Board Computer 30 through monitor lead 35. The Single Board Computer 30 will transmit signals to the various system components via transmit lead 36 for radio frequency transmission from RF Radio Modem 10.

User input can be via the USB Keyboard 50 or Touch Screen 40, to assess system component status or initiate control actions such as disconnecting or connecting battery chargers or obtain system component function status.

FIG. 4 comprises the following components, described more fully in electronic terms. Radio Modem 10 is a radio transceiver, FM radio, USART (Universal serial asynchronous radio transmission). Radio Modem 10 is a module that utilizes frequency modulation at a 433 MHz carrier to transmit digital data on a semi-duplex mode, utilizing 1 Watt of power.

Power source 16 is 5 Volts to power Radio Modem 10. Antenna 17 is a radio antenna, micro connector, and externally mounted unipolar antenna. Antenna 17 is tuned (by length) for UHF 433 MHz.

Single Board Computer 30 is a dedicated single board computer, a Micro PC running in a Windows environment. Lead 31 is a LAN connection between Touch Screen 40 and Single Board Computer 30. Lead 32 is a VGA monitor signal lead between Single Board Computer 30 and Touch Screen 40. Lead 33 is a power feed to Touch Screen 40. Lead 34 is an output lead from USB Key Board 34 to Single Board Computer 30.

Lead 35 is a Serial Data transmission line to Single Board Computer 30 at 9600 baud, 8 bit, parity none, no stops, using a single USB to Serial port adaptor (Tans Line). Lead 36 is a Serial Data receiving line to Single Board Computer 30 at 9600 baud, 8 bit, parity none, no stops, using a single USB to Serial port adaptor (Receiving line).

Touch Screen 40 is a computer flat screen with touchscreen feature. USB Key Board 50 is a PC USB keyboard (Removable. Used only for programming features). Lead 51 is a USB Key Board 50 line (To be disconnected and removed after programming and reset).

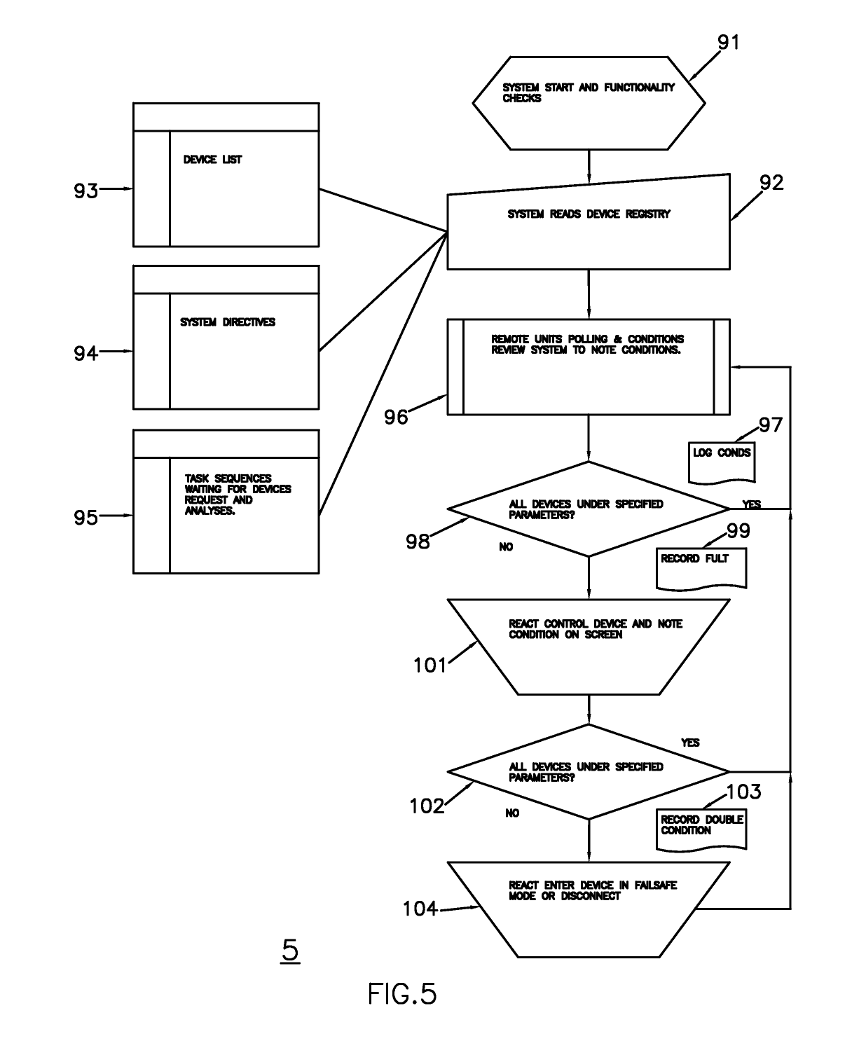

FIG. 5 illustrates an algorithm of an Automatic Device Sweep 5 of the components of the present invention. Beginning with a “System start and functionality checks” 91, the “System reads a device registry” 92 with inputs from a “Device list” 93, “System directives” 94, and “Task sequences waiting for devices requests and analyses” 95.

Upon completion of the device checks and completion of its registry, the system continues to “Remote units polling and conditions review of the system conditions” 96. A system decision point is next, are “All devices under specified parameters” 98, if yes the system “Logs conditions” 97 and returns to its previous status of “Remote Units polling and conditions review of Systems” 96.

If all devices are not within specified parameters then the system proceeds to “Record fault” 99, recording which components are not within specified parameters.

The system further continues to poll the components to “React to Control device and note condition on screen” 101 and further polls to see if “All devices are under specified parameters” 102. If this is the case then the system records under “Log conditions” 97 and returns system control back to “Remote Units polling” 96, if all devices are not under specified parameters, then the system continues to “React to enter device in failsafe mode or disconnect the device” 104 then further logs this action on “Log conditions” 97.

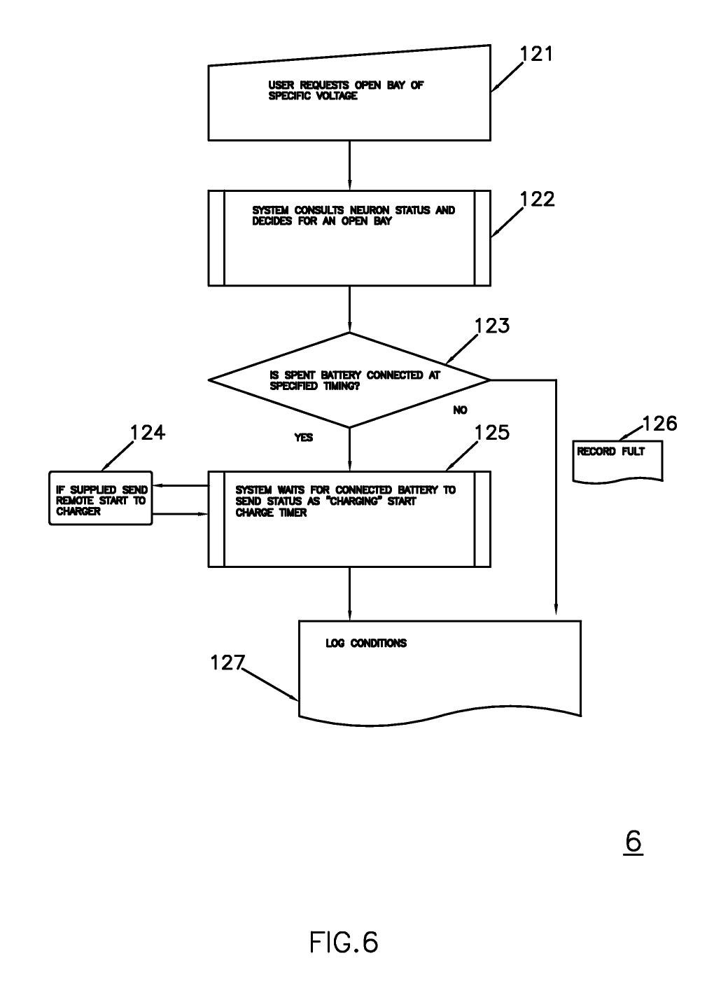

Turning now to FIG. 6 which illustrates an algorithm of the present invention's Battery Charge request 6. A “User requests open bay of specific voltage” 121 and the system further proceeds to “System consults Neuron status and decides for an open bay” 122. The system then decides “Is spent battery connected at specified timing” 123, if no, then the system “Records fault” 126 and further “Logs conditions” 127. If the decision is yes, the spent battery is connected at specified timing then the system proceeds to “System waits for connected battery to send status as “Charging” and starts charge timer” 125, if the battery is not charging the system sends “remote start to Charger” 124. If the battery starts charging then this is logged into “Log conditions” 127.

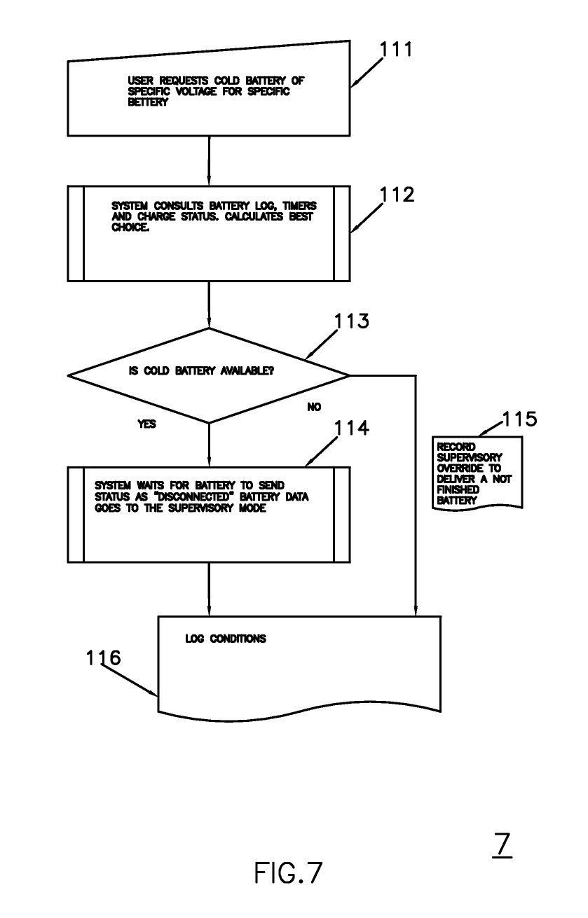

Turning further to FIG. 7 which illustrates an algorithm of a Battery Request 7, “User requests cold battery of specific voltage for specific battery” 111, then the system proceeds to “System consults Battery log, timers and charge status and calculates best choice” 112.

A decision is necessary from the system “Is cold battery available” 113, if no, then the system goes to “Record supervisory override to deliver a not finished battery” 115 and proceeds to “Log conditions” 116.

If a cold battery is available the system goes to “System waits for battery to send status as disconnected and battery data goes to the supervisory mode” 114 and further logs this in “Log conditions” 116.

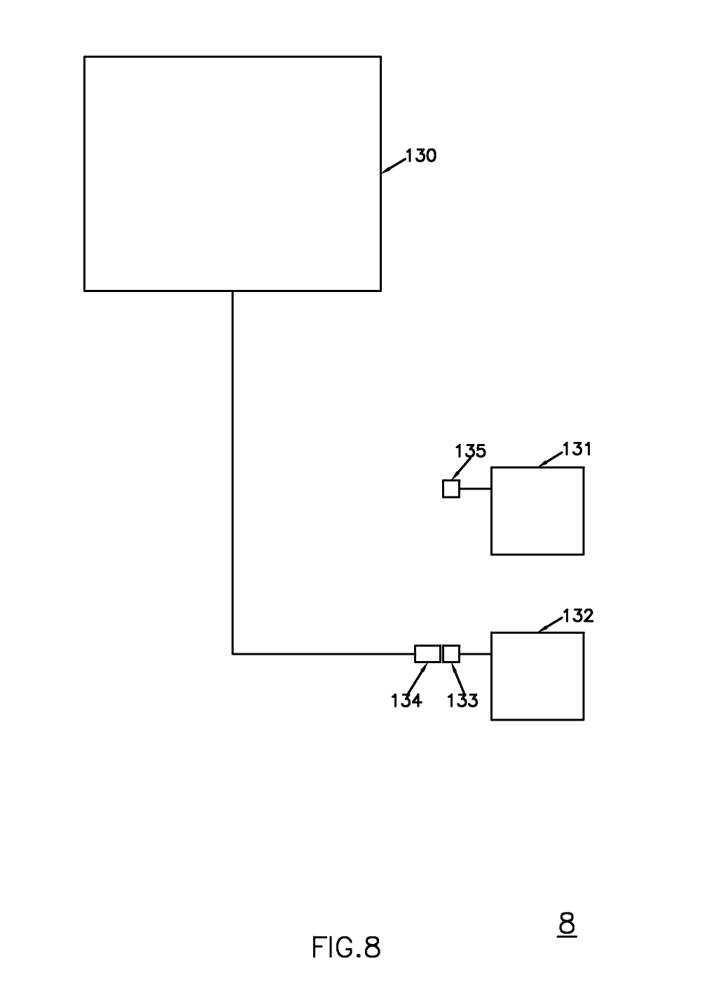

Turning now to FIG. 8 which illustrates a Traditional Battery Rack 8 showing a Battery Charger 130 connected to a Battery 132, showing the traditional connection of one battery charger to one battery. Battery Charger 130 connects to Battery 132 by means of a single male plug 134 connecting with a single female plug 133. As shown in FIG. 8, Battery 131 is not connected which illustrates the inefficiency of traditional battery charging in the industry.

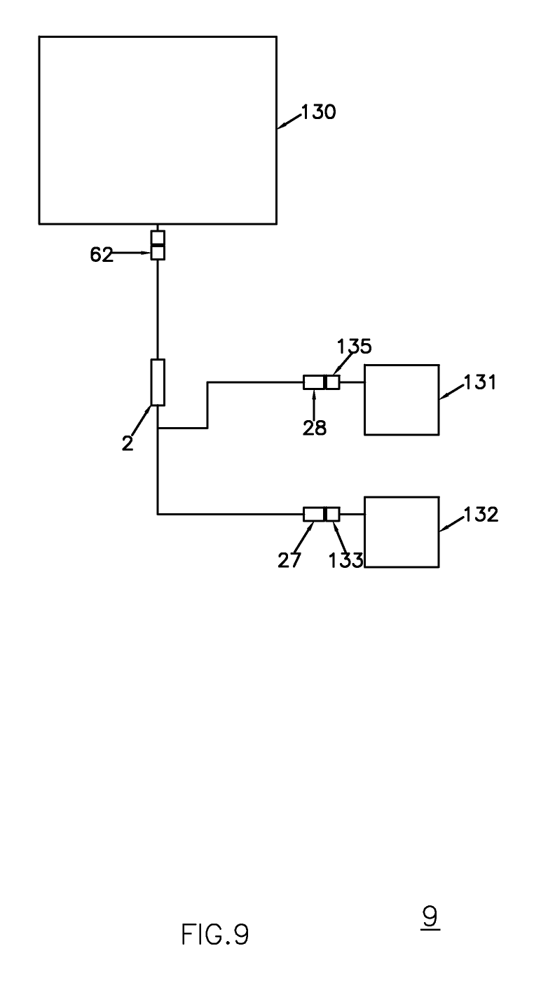

Turning now to FIG. 9 which illustrates a battery charging operation with components of the present invention, the Smart Battery Administration System. Battery Charger 130 is connected to a Neuron plug 62 which further connects to a Neuron 2 mounted on a heat sink containing all Neuron 2 circuitry as noted in FIG. 2. One Neuron 2 male connector 27 is connected to Battery 132 female plug 135, and another Neuron male connector 28 is connected to Battery 131 female plug 135. Illustrated in FIG. 9 is a Monitor and Control Station 4 normally mounted on the battery rack housing Battery Charger 130 and both Battery 131 and Battery 132.

FIG. 9 shows a new charging method with the components of the present invention, thereby doubling the efficiency of traditional battery charging techniques and improving overall efficiencies of fork lift operations, and other industry operations based on industrial batteries for powering of industrial equipment.

### Operational Advantages

To further explain the functionality of the Smart Battery Administration System (S-BAS), and the advantages over prior art, the S-BAS system has as a main premise the optimal charge-cooling-usage cycle of all forklift batteries available at a site. At a regular warehouse operation, an electric forklift is designed to use one charged battery per 8 hour shift, with a “normal” battery charger capacity of one full charge every 8 hours and cooling (disconnected) time of 8 hours (in the S-BAS system, these times are programmable, according to each battery's specified requirements).

At a standard installation, as illustrated in FIG. 8, a battery charger station has one connector plugged to one battery under charge for 8 hours and one charged battery cooling down. When a spent battery is removed from a forklift, it is connected to the battery charger, the newly charged battery is disconnected to cool off and the other battery charged, the cold battery which is charged is installed back in the forklift for the current shift service.

This traditional charging cycle is widely adopted in the industry to minimize handling in battery changes to once per shift, minimize equipment weight by design and the correct (and safe) utilization of the battery charger equipment and the current power technology. It is apparent that the traditional charging technique is not optimal for increased efficiency of battery charging techniques.

The S-BAS system is designed as an innovative and advantageous battery charging management system to increase efficiency of battery charging techniques. The S-BAS system is designed for new installations as well as a retrofit or addition to existing battery charging racks.

The S-BAS system uses a Monitor and Control Base 4 for running polling routines and displaying and storing data. This Monitor and Control Base 4 has reporting and database capabilities that are a good decision making tool.

In operation of the S-BAS system, each battery charger is dedicated to charge one spent battery every eight hours without manual starts or supervision of any kind, based on the charge qualities and parametric data of each battery that is connected to it. Each battery charger will be fitted with an internal module, a Charger Remote Control 1 as shown in FIG. 1, that will control battery charger connect or disconnect functions through monitoring from the Monitor and Control Base 4 of specific conditions of the various components of the present invention. The S-BAS system will also manage charge and cooling timing of batteries.

Each Charger Remote Control 1 and Battery Sensor 3, as shown in FIG. 3, will be polled to transmit status and identification, providing real time data of present battery condition, a feature which is necessary to identify the batteries as they are connected for charge cycle, but will also detect malfunctions in battery charging equipment, or a deficient battery charging service due to malfunctioning equipment.

The Monitor and Control Base 4 sees the data traffic and the power parameters of each component comprising the S-BAS system, and provides the on-off times for each battery charge. The operator will have choices of open bays to connect spent batteries and harvest cold batteries in accordance with well monitored times, but also the S-BAS system will monitor cycles and charge parameters, providing information such as misuse, premature equipment failure conditions, maintenance (battery wash, electrolyte refill) orders and usage statistics.

The Monitor and Control Base 4 has one interface, a touch screen monitor, inside a heavy duty enclosure, mounted on the battery extractor or on the charging rack itself. The Monitor and Control Base 4 connects to each Neuron 2, each Battery Sensor 3 and each battery charger's Charger Remote Control 1 connecting to these various system components by radio frequency, using internal radio modems in each system component.

At any time, operators will be able to request a battery charge or request the battery with the longest cooling time, the S-BAS system will point to the available open bay and provide a battery to retrieve.

Because the batteries remain plugged in, even in the cool off period, premature battery failure can be also detected by the S-BAS system.

The touch screen display in the Monitor and Control Base 4 will present the user with a menu to request a bay for a spent Cattery and to request a cold, charged battery; the Monitor and Control Base 4 will present the user the best choice and a list of technical data for the units in the exchange, plus an automated list of maintenance requirements with supervisory release, and also present this data and all charging system irregularities to a designated file in the connected network.

### Interaction of Components

To fully disclose the interaction of the components of the Smart Battery Administration System (S-BAS), the following is a further disclosure of the functional interaction of the system components. The S-BAS system is comprised of the following components:

a) A remote control/monitor for each battery charger, coupled to its internal circuit, labeled Charger Remote Control 1, described more fully in FIG. 1.
b) An intelligent charge harness consisting of one or more power nodes or Neurons 2 per battery charger, the Neuron 2 illustrated in FIG. 2. In the case where an end user has one charger per each battery or one and one half battery, these Neurons 2 will not be required, only remote Charger Remote Control 1, Battery Sensor 3, and a Monitor and Control Station 4.
c) A Battery Sensor 3 per each battery, illustrated in FIG. 3.
d) One Monitor and Control Station 4, illustrated in FIG. 4.

Each of these S-BAS system components will be described more fully in the following descriptions:

### a) Charger Remote Control 1, Illustrated in FIG. 1

A brief description of battery chargers will describe more clearly how the Charger Remote Control 1 of the present invention functions in the Smart Battery Administration System (S-BAS). The S-BAS system is designed to perform at new battery centers as well as a retrofit to older model battery chargers. The vast majority of modern battery chargers are provided with:
1) “Fault Indicator” (via a red light or digital display). Sometimes battery chargers detect lower than normal voltage on batteries and protect the circuit from high inrush current. Other faults may include additional features depending on the manufacturer.
2) “Charging” status (via a red/orange light or digital display), meaning that the battery is connected and is being charged.
3) “Ready” status that indicates that the battery has been charged and the battery charger has stopped charging.
4) “Stop Charging” button. This push button interrupts the charging cycle and is manually activated by an operator.
5) “Equalize” button. This push button starts the equalizing cycle feature of the battery charger, the battery must be plugged in order to activate this option.
6) “Charge Start”. Not all models include this feature, but some battery chargers require a start command in order to start charging the battery, which is still done by manually pressing a button or setting a timer.

To cover these battery charger functions, the S-BAS system is designed to have a Charger Remote Control 3 installed at the battery charger and be controlled and monitored by a Monitor and Control Station 4.

The S-BAS system has been designed to perform at new battery centers as well as a retrofit to older model battery chargers, where the “Charge Start” function is still done by manually pressing a button or setting a timer. To cover these functions, the S-BAS system is designed to have a Charger Remote Control 3 installed at the battery charger, and these remote controls communicate with the Monitor and Control Station 4 via radio frequency transmission.

### b) Neuron 2, Illustrated in FIG. 2

Each Neuron 2 consists of a power input feeding from the battery charger (or from another primary Neuron 2); inside, the Neuron 2 module has a distribution network consisting of three solid state, high current relays, 24, 25, and 26, one for each output connector 27, connector 28, and connector 29. In series with the input connector 62, a current shunt 42 measures the current going thru the Neuron 2 circuit, as illustrated in FIG. 2. From the input connector 62 and each one of the output connectors, 27, 28, and 29, an insulated parasitic current draw feeds the universal regulator 65 that powers the programmable microcontroller 20 and RF Radio Modem 10 transceiver. The programmable microcontroller 20 effectively measures the voltage to and from each output connector 27, 28, and 29 and provides a connection status when polled form the Monitor and Control Station 4. In this way, each Neuron 2 can act independently to protect itself and the equipment, but also reports and obeys the “connect” and “disconnect” commands from the Monitor and Control Station 4 Console. With the triple output connectors 27, 28, and 29, there is always going to be a free output connector to connect a battery, or if the charge rack is fitted with rapid battery chargers, the Neuron 2 can feed a secondary rapid battery charger, one which adds battery capacity and even create a network of Neurons 2, where each battery can be addressed to a battery charger, even if is on top of an adjacent column.

The battery connectors 62, 27, 28, and 29 are universal; the input connector 62 goes directly to the battery charger, the output connectors 27, 28, and 29 go directly to batteries or to other Neurons 2. The installation is designed to be quickly adaptable to new battery systems or retrofit to older battery systems.

### c) Battery Sensor 3, Illustrated in FIG. 3

Each battery is fitted with a Battery Sensor 3 that verifies electrical parameters and provides status when polled via radio frequency signals from a Monitor and Control Station 4 to RF Radio Modem 10 of the Battery Sensor 3, as shown in FIG. 3. In the case that a battery leaves the range of the Monitor and Control Station 4, the Battery Sensor 3 will remain drawing very low current until is polled again. If the battery does not report status at the programmed intervals, the Monitor and Control Station 4 will consider it missing from system monitoring and will report out a deviation notice.

Once a battery is connected to the S-BAS system, the Monitor and Control Station 4 verifies its serial number and remotely analyzes the electrical usage and new charge parameters through a Battery Sensor 3.

### d) Monitor and Control Station 4, Illustrated in FIG. 4

The Monitor and Control Station 4 is the brain of the system and performs a sweep polling of all the registered system components and collects the status of each component. Because the Monitor and Control Station 4 specifies and knows exactly the electrical parameters of each system component, ordering the connection or disconnection of the Neuron's 2 relays as required by the program, and knows exactly the expected behavior of each device, noting deviations made by equipment malfunction or operator negligence.

All the RF Radio Modems 10 in the S-BAS system are transceivers, designed to listen first for a polling command then, if called, the Charger Remote Control 1 units will respond with the required data. The Monitor and Control Station 4 has a registry of all the monitored equipment.

As shown in FIG. 4 the Monitor and Control Station 4 utilizes a single board microcomputer 30 that controls all peripherals and provides a shared file on a network, where all the data, events and flags will be noted.

At any given time the operator will be able to request an available charging bay, the S-BAS system will assign it to a battery and will wait for the connection. At another time, the operator will request a charged battery. The S-BAS system will provide a battery in a First in First out basis. If batteries are required without completing the mandatory cooling time (which will be recognized by a premature disconnection); then the S-BAS system will require a supervisory override. Monitor and Control Station 4 will guide the operator to facilitate the tasks and if events that should take place never happen, it will provide a supervisory override to justify and note those events as well.

The S-BAS will collect and store information on a server. This information is key to monitor a healthy fleet, to maximize the equipment usage and durability.

Having fully described and disclosed the present invention and preferred embodiments thereof in such clear and concise terms as to enable those skilled in the art to understand and practice same, the invention claimed is:

1. A smart battery administration system comprising:
a battery charger;
a charger remote control for each battery charger;
an intelligent charge harness;
a power node or plurality of power nodes named neurons per battery charger;
a battery sensor per each battery;
a central monitor and control station; and
a plurality of radio modems attached to components of the smart battery administration system.

2. A smart battery administration system as claimed in claim 1 wherein the battery charger is an industrial battery charger with direct current output leads to charge industrial batteries, coupled with a charger remote control.

3. A smart battery administration system as claimed in claim 1 wherein the charger remote control for each battery charger monitors battery charger parameters such as voltage and current of the battery charger.

4. A smart battery administration system as claimed in claim 1 wherein the charger remote control monitors and controls battery charger connection, on or off according to control signals from a central monitor and control station to charge an industrial battery.

5. A smart battery administration system as claimed in claim 1 wherein the charger remote control is controlled via radio frequency transmission from a central monitor and control station.

6. A smart battery administration system as claimed in claim 1 wherein an intelligent charge harness distributes power from a battery charger or plurality of battery chargers at a station or rack, to one or a plurality of industrial batteries.

7. A smart battery administration system as claimed in claim 1 wherein the intelligent charge harness comprises one or a plurality of control nodes named neurons, powered by the battery charger or industrial batteries.

8. A smart battery administration system as claimed in claim 1 wherein the neurons collect and transmit power data parameters to a central monitor and control station via radio frequency transmission.

9. A smart battery administration system as claimed in claim 1 wherein the neurons receive control and connection orders from a central monitor and control station via radio frequency transmission.

10. A smart battery administration system as claimed in claim 1 wherein the battery sensor verifies electrical parameters of the battery and provides these electrical parameters to a central monitor and control station when polled by the central monitor and control station via radio frequency transmission.

11. A smart battery administration system as claimed in claim 1 wherein the central monitor and control station performs a sweep polling of all smart battery administration system components and collects electrical parameters and status of each component via radio frequency transmission.

12. A smart battery administration system as claimed in claim 1 wherein the central monitor and control station transmits electrical control orders to connect or disconnect the neuron's relays between the battery chargers and batteries.

13. A smart battery administration system as claimed in claim 1 wherein the radio modems are transceivers, capable of monitoring and transmitting, which monitor for a polling command to respond by transmitting required data to the central monitor and control station.

14. A smart battery charging and control system comprising:
a charging means;
a charging control for each charging means;
an intelligent charging distribution means;
a power node or plurality of power nodes per each charging means;
a battery sensing means per each battery;
a central monitoring and control means to monitor and control all components of the smart battery charging and control system;
a communications means for each component of the smart battery charging and control system to communicate with a central monitoring and control means; and
a communications protocol to poll each component of the smart battery charging and control system to identify present condition of each component and take appropriate control action according to present system conditions.

15. A smart battery charging and control system as in claim 14 wherein a charging means is an industrial battery charger.

16. A smart battery charging and control system as in claim 14 wherein a charging control for a charging means is an electronic monitoring and control device to monitor status of the charging means and control the operation of a charging means, communicating and receiving control commands from a central monitoring and control means.

17. A smart battery charging and control system as in claim 14 wherein an intelligent charging distribution means is an intelligent charging harness connected to a charging means or a plurality of charging means and also connected to a battery or a plurality of batteries.

18. A smart battery charging and control system as in claim 14 wherein a power node or a plurality of power nodes for a charging means is an electronic device of the present invention which monitors and controls a charging means or plurality of charging means to distribute power through an intelligent harness to a battery or a plurality of batteries, monitoring and communicating system status to a system monitor and control means and receiving control commands from the system monitoring and control means.

19. A smart battery charging and control system as in claim 14 wherein a communications protocol to poll each component of the smart battery charging and control system to identify present condition of each component and take appropriate control action according to present system conditions is a computer program at each system component's microcontroller to integrate polling and control of each system component, communicating via radio frequency transmission.

20. A battery charging system for battery charging automation and battery charging optimization comprising:
a battery charging system that maximizes automation of a battery charging process;
a battery charging system that controls battery charge time duration and cooling time duration;
a battery charging system that acquires necessary data of the battery charging process in real time;
a battery charging system that establishes automatic maintenance notifications;
a battery charging system that establishes automatic maintenance control;
a battery charging system that optimizes battery charger utilization;
a battery charging system that minimizes human error in the logistics of the battery charging process;
a battery charging system that avoids arbitrary battery charging and discharging durations and timing; and
a battery charging system that reduces premature battery damage.
